(19) United States
(12) Patent Application Publication
(10) Pub. No.: US 2026/0309764 A1
(43) Pub. Date: Oct. 8, 2026

(54) Method of monitoring the integrity and determining damage location on body of object

(71) Applicant: Daniel Mamchik, Hillsboro, OR (US)

(72) Inventor: Daniel Mamchik, Hillsboro, OR (US)

(21) Appl. No.: 19/096,691

(22) Filed: Mar. 31, 2025

(51) Int. Cl. G01R 31/11; G08B 1/08

(52) U.S. Cl. CPC G01R 31/11; G08B 1/08

(57) ABSTRACT

The method described in this patent is a novel low-cost method of determining the integrity of the monitored body of object. The method is based on using a sensor, which consists of a cable, densely routed over the monitored surface, and a monitor, which consists of the virtual Time Domain Reflectometer, created at the communication interface of the microcontroller. The detection is based on sending a specially constructed binary sequence and analyzing the returned signal to extract the length of connected cable. By measuring the undamaged length of the cable, the coordinates of any damage on the monitored surface can be determined.

### FIELD OF THE INVENTION

This invention relates to a method for detecting the location of damage across various monitored surfaces, including but not limited to spacecraft hulls, aircraft structures, wind turbine blades, vehicle bodies, pipelines, structural walls, building exteriors, industrial machinery, and other similar surfaces.

### BACKGROUND OF THE INVENTION

In recent years, there has been an exponential growth in the number of objects launched into space, with thousands of satellites being added to the constellation each year. There is also an increasing demand to reduce the cost of constructing spacecraft while maintaining essential services, including monitoring the integrity of the hulls. Current approaches for detecting damage typically include smart panels, which are effective but introduce significant cost and weight to spacecraft. As a result, spacecraft manufacturers often exclude damage detection systems to reduce costs, leaving potential structural damage undetected. This invention addresses the need for a cost-effective solution to monitor the integrity of spacecraft hulls, providing a means to detect and locate damage without adding significant weight or expense.

A similar need exists in other industries, including aircraft, vehicles, wind turbines, pipelines, and structural walls, where maintaining the integrity of critical surfaces is essential for safety and operational efficiency. In these areas, there is a growing interest in solutions that enable damage detection while minimizing additional costs and weight.

### OBJECTS OF THE INVENTION

The object of the invention is to provide a method for monitoring specific areas of a structure to detect and accurately locate any breaches in the monitored area, while offering a cost-effective, lightweight, and scalable solution that can be applied across a wide range of surfaces, including but not limited to spacecraft, aircraft, vehicles, wind turbine blades, pipelines, and other critical infrastructure.

### BRIEF SUMMARY OF THE INVENTION

This invention proposes a method for monitoring and detecting damage on a monitored surface using a sensor consisting of a cable routed across the surface, as shown in FIG. 1. The cable may be implemented in various forms, such as an actual wire, a thin film embedded in a flexible Printed Circuit Board (PCB), or a metallic pattern applied over the surface, provided that appropriate insulation is used. The layout of the cable must be carefully planned to avoid self-intersections, ensuring that its length accurately corresponds to a coordinate system on the monitored surface. This arrangement allows the cable length to directly correspond to specific coordinates on the surface grid.

When damage occurs to the monitored surface, it results in the shortening of the cable, reducing its effective length. By measuring the undamaged length of the cable, the exact location of the damage can be determined based on the known cable layout.

For detecting the undamaged length of the cable, the invention utilizes Time Domain Reflectometry (TDR) with a novel design. The TDR design leverages the serial communication interface of microcontrollers, offering a cost-effective and efficient solution for measuring cable length. This approach capitalizes on existing microcontroller hardware, reducing the need for specialized equipment and lowering overall system costs. In one embodiment, the Serial Peripheral Interface (SPI) of the microcontroller is employed for measurement. However, other serial interfaces may also be used depending on the application, with the appropriate bit string constructed for different encoding schemes.

The microcontroller sends out a binary sequence that forms a step-like pattern resembling a Heaviside function, starting with a long series of “0” followed by a long series of “1” , as shown in FIG. 401. The length of each series of “0” and “1” is determined by the clock rate of the communication channel and the length of the connected cable. A faster clock rate improves the resolution of the measurement, while a longer cable requires a longer string of bits to ensure that the signal remains distinguishable and accurate for detecting changes in the cable.

As the signal travels from the microcontroller output to the input, the presence of the connected sensor cable leads to signal distortion, as shown in FIG. 402. To restore the signal, an electronic conditioning circuit is employed, which may include components like a Schmitt Trigger and a voltage divider. The restored signal is then sent to the microcontroller, which determines the number of bits that were lost during the transition (as shown in FIG. 405). From the clock rate and the number of bits lost, the microcontroller can calculate the undamaged length of the cable, thereby determining the coordinates of any damage on the surface.

### BRIEF DESCRIPTION OF THE DRAWING

FIG. 1: An example of the layout of the cable arranged over the monitored area, covering the entire surface in a non-intersecting path. The cable is connected at a single point, forming a coordinate system that correlates the cable length to specific locations on the surface.

FIG. 2: A depiction of damage to the cable, including the comparison between the damaged portion and the total length of the cable.

FIG. 3: Schematic of the complete system, showing the microcontroller with input, output, and ground pins, the cable through which signals are transmitted, a Schmitt Trigger, and a voltage divider.

FIG. 4: Depictions of the signal transmission through the cable arranged over the area, illustrating how the signals change from output to input throughout the system.

### DETAILED DESCRIPTION OF THE DRAWINGS

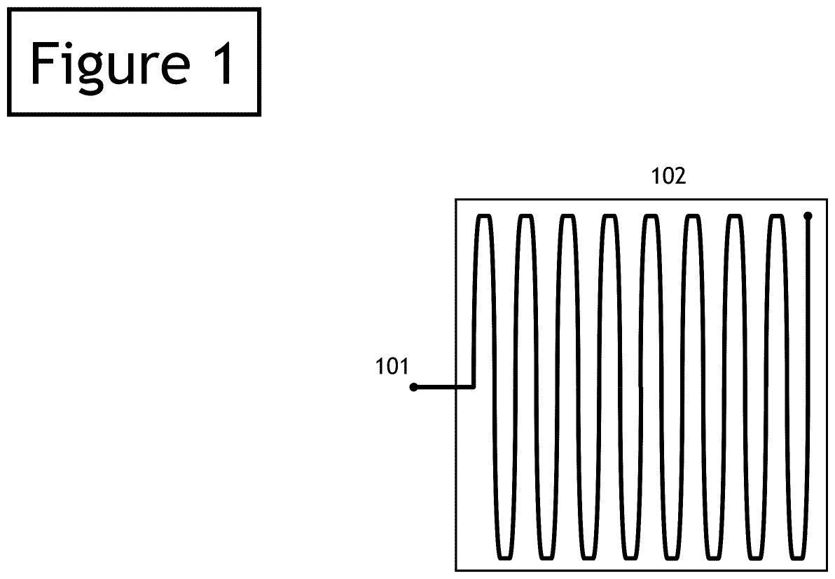

FIG. 1 shows the area of detection, where the cable is arranged in a known pattern (102) around the entire monitored area, with the cable connected at one point (101).

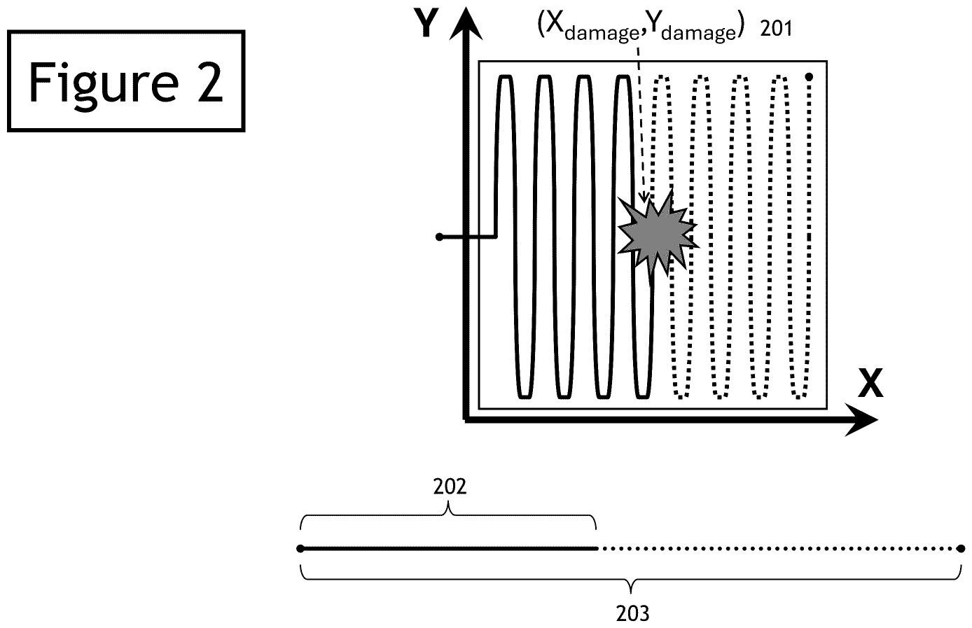

FIG. 2 shows the cable damaged at a specific point in the monitored area (201). By comparing the length of the cable from the start to the damage point (202) with the original undamaged length of the cable (203), the damage point (201) can be located, assuming the cable layout is known.

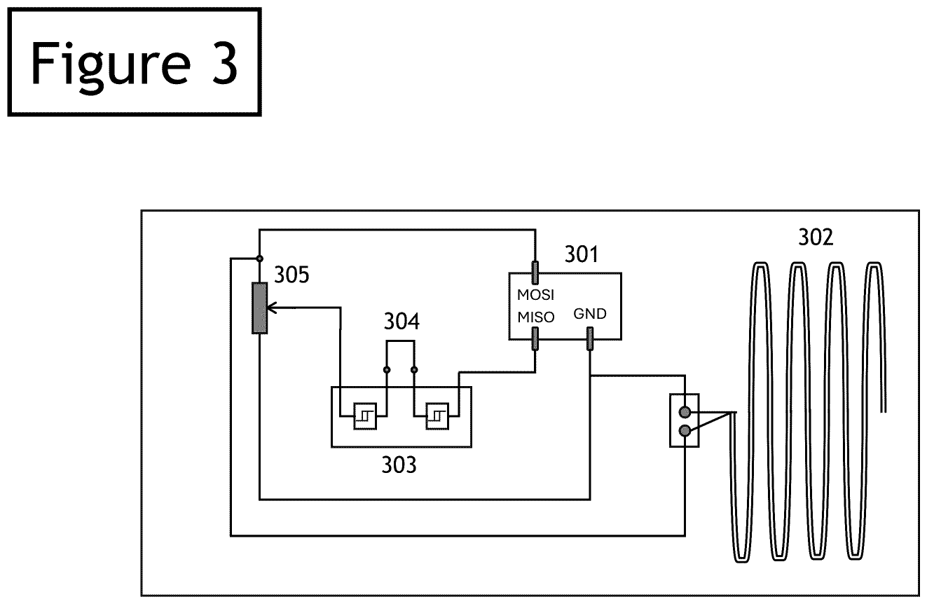

FIG. 3 illustrates the complete system, where a microcontroller (301) with input and output capabilities sends binary sequences to the cable arranged over the area (302). The distorted signal from the cable (302) returns through a voltage divider (305) which reduces the signal's amplitude. The conditioned signal is then passed through a Schmitt Trigger (303) to restore signal integrity, allowing comparison between the original and final signals. The signal is passed through the Schmitt Trigger twice (304) to ensure it remains non-inverted for accurate comparison.

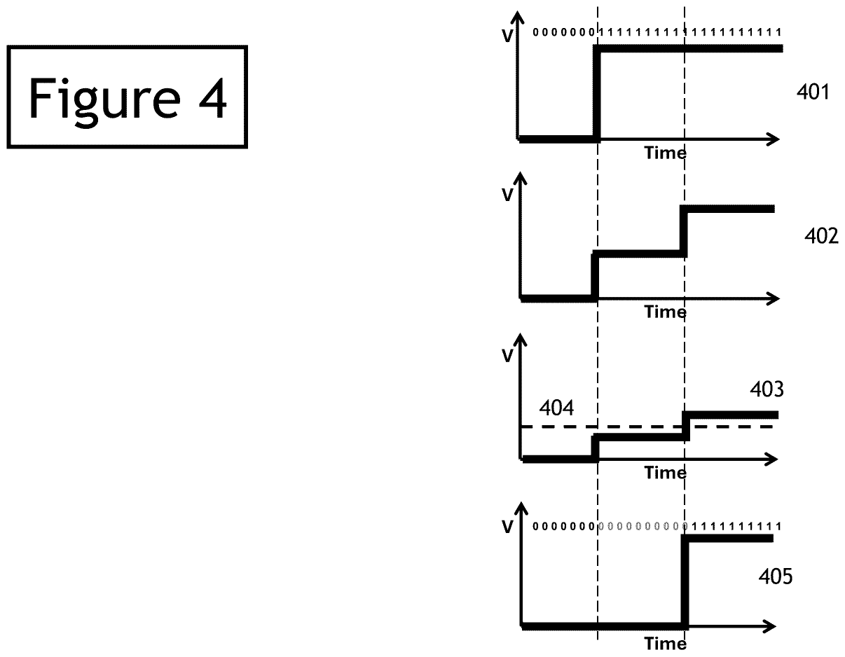

As shown in FIG. 4, the signals change as they travel through the system. The original signal (401) is sent through the sensing wire (101) and becomes distorted (402). The distorted signal is then passed through a voltage divider to reduce its amplitude (403) below the Schmitt Trigger upper threshold (404) and is processed twice through a Schmitt Trigger for the comparison with the original signal (401). The final signal (405) is sent back to the microcontroller for processing and determination of the cable length.

What is claimed is:

1. A method for detecting the existence and location of damage to a monitored surface of an object, comprising:
A. A sensor consisting of a single cable routed across the monitored area; and
B. A monitor comprising of a microcontroller and an electronic circuit that processes the reflected signal returned from the sensor, analyzes the signal distortion caused by damage, and calculates the location of the damage based on the measured length of the damaged cable.

2. The sensor of claim 1, wherein the cable is routed across the entire monitored area in a non-self-intersecting and continuous arrangement.

3. The sensor of claim 2, wherein the cable is selected from the group consisting of an individual wire, a flexible PCB, a metallic pattern applied over the monitored surface with appropriate insulating material or coatings applied to prevent short circuits, a printed trace, or any other conductive or similar materials or methods.

4. The monitor of claim 1, wherein the microcontroller includes a serial interface with input and output ports and is connected to an electronic circuit for signal conditioning, wherein the circuit processes the reflected signal to detect damage.

5. The electronic circuit of claim 4, comprising:
A. Two Schmitt Triggers connected serially, or
B. A single Schmitt Trigger, or
C. Other signal conditioning circuits;
and an optional circuitry to reduce the amplitude of the signal, such as a voltage divider, for conditioning the reflected signal.

6. The signal sent by the microcontroller in claim 1, comprising a binary sequence that forms a step-like pattern resembling the edge of a Heaviside function, where the number of “0” and “1” in the signal is determined by the clock rate of the microcontroller's communication interface and the length of the monitored cable, such that the signal length encompasses the cable length.

7. The method of claim 1, wherein the detection is based on measuring the number of bits that were lost as the signal travels from output to input and using the clock rate and the bit transition data to calculate the undamaged length of the cable, thereby determining the location of the damage relative to the known cable routing.

8. The method of claim 1, wherein the coordinates of the damage are determined based on the measured damaged length of the cable and the known routing of the cable over the monitored surface.

9. The method of claim 1, wherein the monitored surface is selected from the group consisting of satellite hulls, spacecraft hulls, aircraft hulls, vehicle hulls, wind turbine blades, mining equipment, oil rigs, power plants, military vehicles, military shelters, underground pipelines, structural walls, building exteriors, device exteriors, marine vessels, industrial machinery, body armor, protective suits including spacesuits, underground storage tanks, and other similar applications.

10. The method of claim 1, wherein the sensor is embedded within or mounted on a flexible substrate to conform to irregular shapes of the monitored surface.

11. The method of claim 1, wherein the electronic circuit comprises an analog-to-digital converter (ADC) for digitizing the reflected signal before processing.

12. The method of claim 1, wherein the location of the damage is calculated based on the difference in signal travel times, with the clock rate determining the resolution of the measurement.

13. The method of claim 1, wherein the signal processing in the electronic circuit is performed in real-time, providing immediate detection of damage upon occurrence.

14. The method of claim 1, wherein the damage detection system is configured to monitor multiple areas simultaneously by routing distinct sensor cables in separate zones or sections of the monitored surface.

15. The method of claim 1, wherein the microcontroller is programmed to issue an alert (e.g., audible, visual, or through wireless communication) when damage is detected, enabling automatic response or further investigation.

16. The method of claim 1, wherein the system includes a wireless communication module to transmit the location of the detected damage to a remote device for monitoring or analysis.

17. The method of claim 1, wherein the system is designed to be retrofitted to existing structures without significant alteration to the monitored surface.

18. The method of claim 1, wherein the sensor cable is routed to create a network of cables over the monitored surface, with each segment of cable monitored separately to detect damage at multiple locations across the surface.

19. The method of claim 1, wherein the system includes a feedback mechanism that dynamically adjusts the signal conditioning parameters (e.g., clock rate, voltage levels, gain) based on the detected characteristics of the reflected signal to optimize damage detection.

20. The method of claim 1, wherein the electronic circuit includes a signal filtering component to minimize noise and false positives when measuring the reflected signal.

21. The method of claim 1, wherein the system includes a diagnostic mode for testing the sensor cable and signal processing system without requiring actual damage, to verify proper functionality and calibration of the system.

22. The method of claim 1, wherein the cable layout is modular, allowing individual sensor cable sections to be replaced, reconfigured, or adjusted without requiring significant reconfiguration of the entire system.

23. The method of claim 1, wherein the system includes an interface that allows the user to manually input the cable layout parameters, enabling the system to calculate the damage location relative to a user-defined coordinate system.

24. The method of claim 1, wherein the sensor cable is embedded in a material that provides mechanical protection, allowing the system to monitor more rugged or difficult-to-access surfaces without compromising performance.

25. The method of claim 1, wherein the system is powered by a low-power source, such as a battery, to enable remote or long-term monitoring in off-grid locations.

26. The method of claim 1, wherein the system is capable of comparing multiple measurements taken at different times to detect damage progression or multiple instances of damage over time.
